(19) United States
(12) Patent Application Publication
(10) Pub. No.: US 2016/0374203 A1
(43) Pub. Date: Dec. 22, 2016

(54) PRINTED CIRCUIT BOARD VIA FUSE

(71) Applicant: Mersen USA Newburyport-MA, LLC, Newburyport, MA (US)

(72) Inventors: Shashank Bakre, Burlington, MA (US); Arthur Gilenberg, Needham, MA (US)

(73) Assignee: Mersen USA Newburyport-MA, LLC, Newburyport, MA (US)

(21) Appl. No.: 15/185,244

(22) Filed: Jun. 17, 2016

Related U.S. Application Data
(60) Provisional application No. 62/181,823, filed on Jun. 19, 2015.

(51) Int. Cl. H05K 1/16; H05K 1/11; H05K 1/02; H05K 1/09

(52) U.S. Cl. CPC H05K 1/16; H05K 1/09; H05K 1/115; H05K 1/0263; H05K 2201/10181; H05K 2201/09563; H05K 2201/09545

(57) ABSTRACT

A printed circuit board (PCB) via fuse including a non-conductive substrate having a pair of terminal conductors, a plurality of jumper conductors and one or more through-hole vias that electrically connect the terminal conductors and jumper conductors. The through-hole vias function as the fuse element of the PCB via fuse.

### RELATED APPLICATIONS

This application claims the benefit of U.S. Provisional Application No. 62/181,823, filed Jun. 19, 2015, which is hereby fully incorporated herein by reference.

### FIELD OF THE INVENTION

The present invention relates generally to the field of fuse devices, and more specifically to a printed circuit board via fuse.

### BACKGROUND OF THE INVENTION

A fuse is a current limiting device used extensively in industry to protect valuable equipment and resources (e.g., a load or source circuit) from damage due to a catastrophic event. In many typical fuses, the fuse element is a metal wire or strip that melts when too much current flows through it, interrupting the circuit that it connects. Short circuits, overloading, mismatched loads, or device failure are the prime reasons for excessive current. A fuse interrupts excessive current (“blows”) that further damage by overheating or fire is prevented. The time and current operating characteristics of fuses are chosen to provide adequate protection without needless interruption. Slow blow fuses are designed to allow harmless short term currents over their rating while still interrupting a sustained overload. Fuses are manufactured in a wide range of current and voltage ratings to protect wiring systems and electrical equipment.

Fuses are typically made according to the following process: (a) define the desired electrical parameters (maximum voltage, maximum operating current, maximum I²t energy rating, maximum interrupting current, etc.); (b) design and build a fuse element from a conductive material, such as silver, copper, aluminum, bimetal, or the like; and (c) insert the fuse element into a housing having a pair of terminals for connecting the fuse element to external contacts (e.g., a fuse holder). A filler material may be provided within the housing to provide thermal management and arc mitigation.

One type of conventional fuse element takes the form of a plurality of parallel thin flat strips of metal with notches formed therein. Another type of conventional fuse element is a bimetal fuse element comprised of a plurality of parallel thin flat strips of bimetal formed of alternating regions of two different metals (e.g., silver and copper). Notches are formed in some of the metal regions (e.g., all of the silver metal regions). The number of alternating metal regions may vary depending upon the desired electrical parameters for the fuse. The length, width, thickness, and number and dimension of each notch of the metal strips comprising the fuse element define the electrical parameters of the fuse.

The fuse elements described above are produced by various mechanical operations (e.g., cutting, stamping, bending, and annealing). The tooling die to form such fuse elements typically takes several weeks to design and build. Production of such fuse elements includes the following drawbacks:
Notch stretching may cause the fuse to open early, and thus fail to achieve the desired electrical parameters.
Bending of the fuse elements may affect operation of the fuse.
Need to handle and transport the fuse elements prior to completing assembly of the fuse.
Need for periodic tool die maintenance for proper stamping and cutting of the fuse element.
Increased time to complete assembly of the fuse due to making and handling of the fuse elements.
Automation of total fuse assembly may create a manufacturing bottleneck due to handling of the fuse element.
As the voltage requirements increase, the length of the fuse must increase.
Arc quenching may require additional components (silicone) or materials that can increase manufacturing costs.
Need to keep inventory of conductive materials having different thicknesses in order to produce fuse elements having different electrical parameters.
Need to dispose of scrap that is generated when stamping the fuse elements.

A printed circuit board (PCB) is well known in the electronics industry for use in forming electronic circuits. The components in the circuit are soldered on pads and each pad is connected to other component using traces which are formed of a conductive material, such as copper, silver, gold or the like. The PCB may also include a fuse element in the form of a “trace fuse.” The trace fuse is comprised of a conductive material, wherein the thickness, width, and length of the conductive material must be varied to define the electrical parameters of the fuse. In this regard, the length of the conductive material defines the voltage rating of the trace fuse (e.g., a greater length increases the voltage rating), while the width and thickness of the conductive material defines the current rating of the trace fuse. A high current will melt the trace fuse. Once the trace fuse is melted, voltage arcing continues to melt the trace fuse until it is extinguished.

The present invention provides a fuse that overcomes the limitations and drawbacks of existing conventional fuse elements and trace fuses.

### SUMMARY OF THE INVENTION

In accordance with the present invention, there is provided a printed circuit board (PCB) via fuse comprising: a non-conductive substrate; first and second terminal conductors formed on the substrate; a plurality of jumper conductors formed on the substrate; and one or more through-hole vias electrically connecting the first and second terminal conductors and the plurality of jumper conductors, wherein said through-hole vias are fuse elements that melt in response to a current overload condition.

An advantage of the present invention is the provision of a PCB via fuse which can be used as a substitute fur both a conventional fuse element and a trace fuse.

Another advantage of the present invention is the provision of a PCB via fuse that is easily modified to achieve various electrical operating parameters.

Still another advantage of the present invention is the provision of a PCB via fuse that does not require tooling and dies to produce stamped elements.

Still another advantage of the present invention is the provision of a PCB via fuse that eliminates the need for a fuse element having a notch that can stretch and cause the fuse element to open earlier than intended.

Still another advantage of the present invention is the provision of a PCB via fuse that eliminates a bendable fuse element.

Still another advantage of the present invention is the provision of a PCB via fuse that eliminates handling and transportation issues prior to full assembly of the fuse.

Still another advantage of the present invention is the provision of a PCB via fuse that eliminates the need for a fuse element that is manufactured using a tool die for stamping and cutting.

Still another advantage of the present invention is the provision of a PCB via fuse that reduces manufacturing time.

Still another advantage of the present invention is the provision of a PCB via fuse that can be assembled in an automated manner.

Yet another advantage of the present invention is the provision of a PCB via fuse that eliminates or reduces the generation of scrap material in the production of a fuse element.

Yet another advantage of the present invention is the provision of a PCB via fuse that achieves different current rating using a single PCB with multiple vias (i.e., closing/opening of vias as needed provides different desired current ratings for the fuse).

Yet another advantage of the present invention is the provision of a PCB via fuse that can be easily manufactured according to “Gerber” files.

These and other advantages will become apparent from the following description of illustrated embodiments taken together with the accompanying drawings and the appended claims.

### BRIEF DESCRIPTION OF THE DRAWINGS

The invention may take physical form in certain parts and arrangement of parts, embodiments of which will be described in detail in the specification and illustrated in the accompanying drawings which form a part hereof, and wherein:

FIG. 1 is a perspective view of a PCB via fuse according to a first embodiment of the present invention;

FIG. 2 is a top plan view of the PCB via fuse shown in FIG. 1;

FIG. 3 is a partial cross-sectional view of the PCB via fuse taken along lines 3-3 of FIG. 2;

FIG. 4 is a bottom plan view of the PCB via fuse shown in FIG. 1;

FIG. 5 is an enlarged partial cross-sectional view of the PCB via fuse, showing a plated through-hole via;

FIG. 6 is a perspective view of a PCB via fuse according to a second embodiment of the present invention; and

FIG. 7 is an enlarged partial cross-sectional view of the PCB via fuse taken along lines 7-7 of FIG. 6, showing a filled through-hole via.

### DETAILED DESCRIPTION OF THE INVENTION

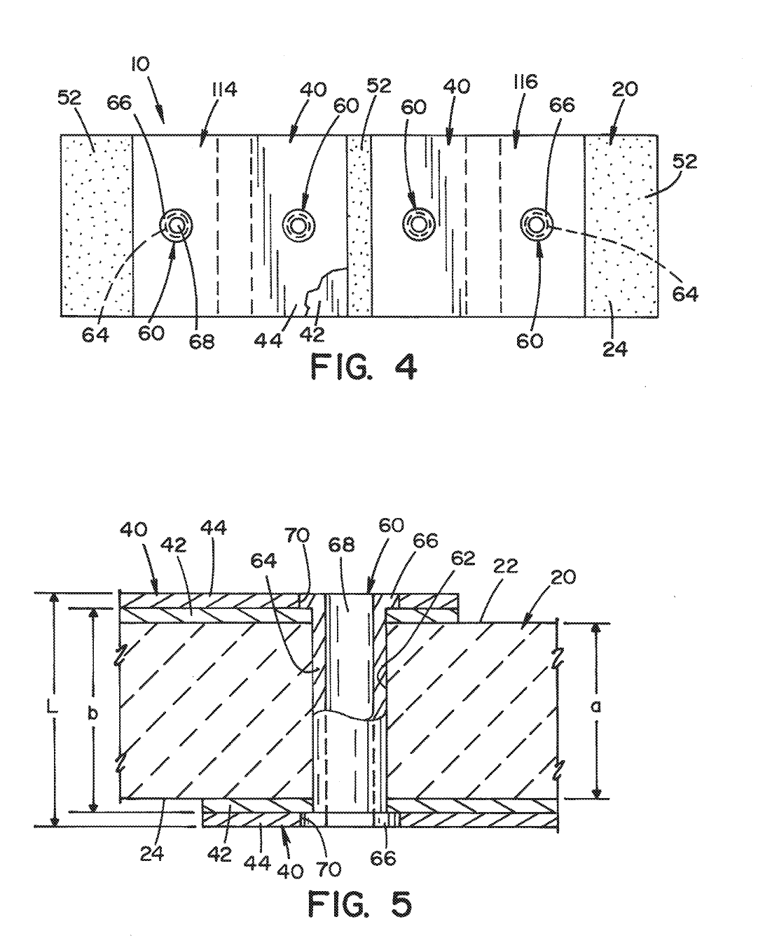

Referring now to the drawings wherein the showings are for the purposes of illustrating embodiments of the invention only and not for the purposes of limiting same, FIG. 1 shows a PCB via fuse 10 according to a first embodiment of the present invention. FIG. 2 is a top plan view of PCB fuse 10 and FIG. 4 is a bottom plan view of PCB fuse 10. PCB fuse 10 is generally comprised of a non-conductive core or substrate 20, upper and lower conducting members 40 respectively formed at upper and lower surfaces 22, 24 of substrate 20, and one or more through-hole vias 60 that extend through substrate 20.

Substrate 20 may take the form of a conventional dielectric material, including, but not limited to, polyimides, fiberglass (e.g., “FR4” rigid fiberglass), ceramic, flexible high-temperature plastics (e.g., Kapton® or the equivalent), epoxies, phenolics, or other suitable electrical insulating material well known to those skilled in the art. In an example embodiment, substrate 20 has a thickness (height) in a range of about 1 mm to about 2 mm, a length in a range of about 1 cm to about 1 m, and a width in a range of about 1 mm to about 10 cm. It should be appreciated that these dimension ranges are illustrative of an example embodiment, and are not intended to limit the scope of the present invention. In this respect, substrate 20 may have alternative dimensions in accordance with the present invention.

In the illustrated embodiment, conducting members 40 take the form of conductive planes comprised of a base layer 42 and a plating layer 44. Base layer 42 and plating layer 44 are comprised of conductive metals. For example, base layer 42 may be comprised of copper, while plating layer 44 may be comprised of copper, silver, tin, gold, palladium, nickel, or other metals and alloys.

Example methods of forming conducting members 40 will now be described. According to one embodiment, base layer 42 is laminated to substrate 20 using an adhesive material and heat, and plating layer 44 is formed on base layer 42 by an electroplating process. According to an alternative embodiment, substrate 20 may be produced such that base layer 42 and plating layer 44 cover the entire upper and lower surfaces 22, 24 thereof. Base layer 42 and plating layer 44 are subject to a conventional metal etching process to remove selected portions of layers 42, 44, thereby creating gaps 52 which define individual conducting members 40, as shown in FIG. 1. It is contemplated that a conventional “off-the-shelf” (single or multilayer) conductor-clad PCB board may be used in connection with the present invention. In an example embodiment, layers 42 and 44 have a thickness (height) in a range of about 1 μm to about 100 μm, a length in a range of about 1 cm to about 1 m, and a width in a range of about 1 mm to about 10 cm. It should be appreciated that these dimension ranges are illustrative of an example embodiment, and are not intended to limit the scope of the present invention. In this respect, layers 42 and 44 may having alternative dimensions in accordance with the present invention.

In accordance with an alternative embodiment of the present invention, it is contemplated conducting members 40 may have a different number of conductive layers than as shown in the illustrated embodiments (e.g., a single conductive layer or three conductive layers). It is further contemplated that the shape of PCB via fuse 10 may be different from the illustrated embodiments.

Conducting members 40 include a pair of terminal conductors 102, 104 and jumper conductors 112, 114 and 116. In the illustrated embodiment, terminal conductors 102 and 104 are located at opposite ends of upper surface 22. Jumper conductor 112 is located on upper surface 22, between terminal conductors 102 and 104. Jumper conductors 114 and 116 are located on lower surface 24. On upper surface 22, each of the conductors 102, 112 and 104 are spaced apart by gaps 52. On lower surface 24, jumper conductors 114 and 116 are likewise space apart by gap 52. The spacing provided by gaps 52 may be determined dependent upon the desired voltage rating of PCB via fuse 10. For example, for a voltage rating of 600V, gap 52 is about 4 mm in the illustrated embodiment.

One or more through-hole vias 60 electrically connect terminal conductors 102, 104 and jumper conductors 112 114 116 to each other, and serve as fuse elements of fuse 10. In this respect, vias 60 will melt in response to a current overload condition, thereby disrupting the flow of current between terminal conductors 102 and 104. As best seen in FIG. 1, vias 60 electrically connect terminal conductor 102 to jumper conductor 114, jumper conductor 114 to jumper conductor 112, jumper conductor 112 to jumper conductor 116, and jumper conductor 116 to terminal conductor 104. Accordingly, a continuous electrical path is provided between terminal conductor 102 and terminal conductor 104.

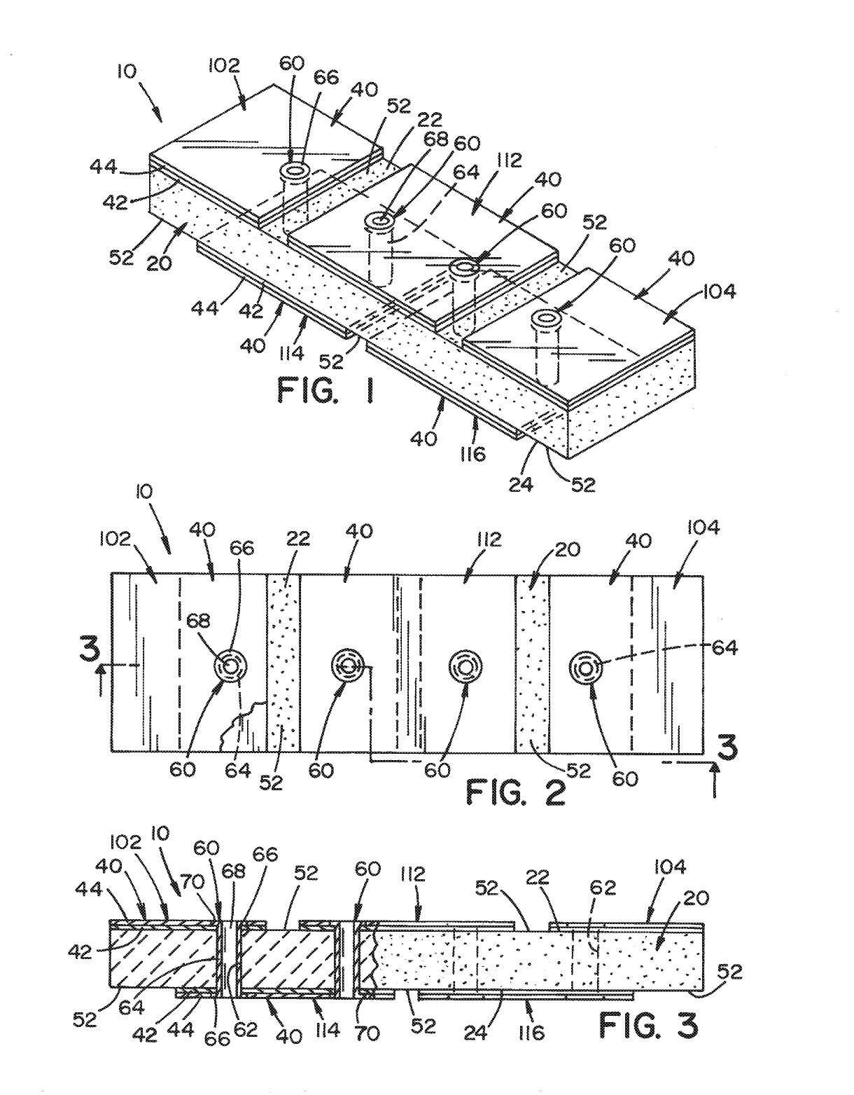

Each via 60 is generally comprised of a barrel portion 64 and a pair of pads 66, as best seen in the cross-sectional views of FIGS. 3 and 5. A through-hole 62 extends through substrate 20 and layers 42 and 44 at upper and lower surfaces 22, 24. Barrel portion 64 is located within through-hole 62. In the embodiment shown in FIGS. 1-5, vias 60 are “plated” through-hole vias. Accordingly, barrel portion 64 forms a hollow conductive cylinder defining a cylindrical opening 68. For example, opening 68 may have a diameter of about 0.8 mm.

Annular clearance holes 70 (also referred to as “antipads”) are formed in layers 44 at upper and lower surfaces 22, 24 to accommodate pads 66. Pads 66 take the form of annular rings located within holes 70 at opposite ends of barrel portion 64. The diameter of hole 70 is larger than the outer diameter of pad 66 to provide a solder clearance. For example, pads 66 may have an outer diameter of about 1.2 mm, and holes 70 may provide an annular clearance space of 50 μm around the outer periphery of pads 66. Pads 66 are dimensioned to have an outer surface that is generally flush with the outer surface of plating layers 44.

In the illustrated embodiment, the length (L) of barrel portion 64 (and likewise via 60) is equal to the sum of: (i) the thickness of substrate 20, (ii) twice the thickness of base layer 42, and (iii) twice the thickness of plating layer 44. With reference to the embodiment illustrated in FIG. 5, length (L) of barrel portion 64 is about 1.636 mm, the thickness of substrate 20 (dimension “a”) is about 1.6 mm, and the thickness of base layer 42 is about 0.009 mm (thus dimension “b” is about 1.618 mm). The foregoing dimensions are examples only, and are not intended to limit the scope of the present invention.

In an example embodiment of the present invention, length (L) of barrel portion 64 is in a range of about 1 mm to about 5 mm. The outer diameter (OD) of barrel portion 64 is in a range of about 0.1 mm to about 1 mm. The inner diameter (ID) of barrel portion 64 is in a range of about 0.05 mm to about 0.95 mm. The outer diameter (O_{DP}) of pad 66 is in a range of about 1.2 mm to about 2.0 mm. The foregoing dimensions determine the current rating of PCB via fuse 10. A maximum current that can “fuse” the plating is calculated in a manner similar to a PCB trace fuse. For via 60 having the foregoing dimension ranges, the maximum current is in a range of about 100 mA to about 30 A.

An example process for forming each via 60 will now be described. First, through-hole 62 is formed by drilling a hole that extends through (i) layer 42 at upper surface 22, (ii) substrate 20, and (iii) layer 42 at lower surface 24. Thereafter, an electroplating process is used to form layer 44 at upper and lower surfaces 22, 24, and to form barrel portion 64 and pads 66. In an alternative process, barrel portion 64 and pads 66 may be formed by lining through-hole 62 with a tube or a rivet. The plating material includes, but is not limited to, copper, silver, tin, gold, palladium, nickel, and other metals and alloys.

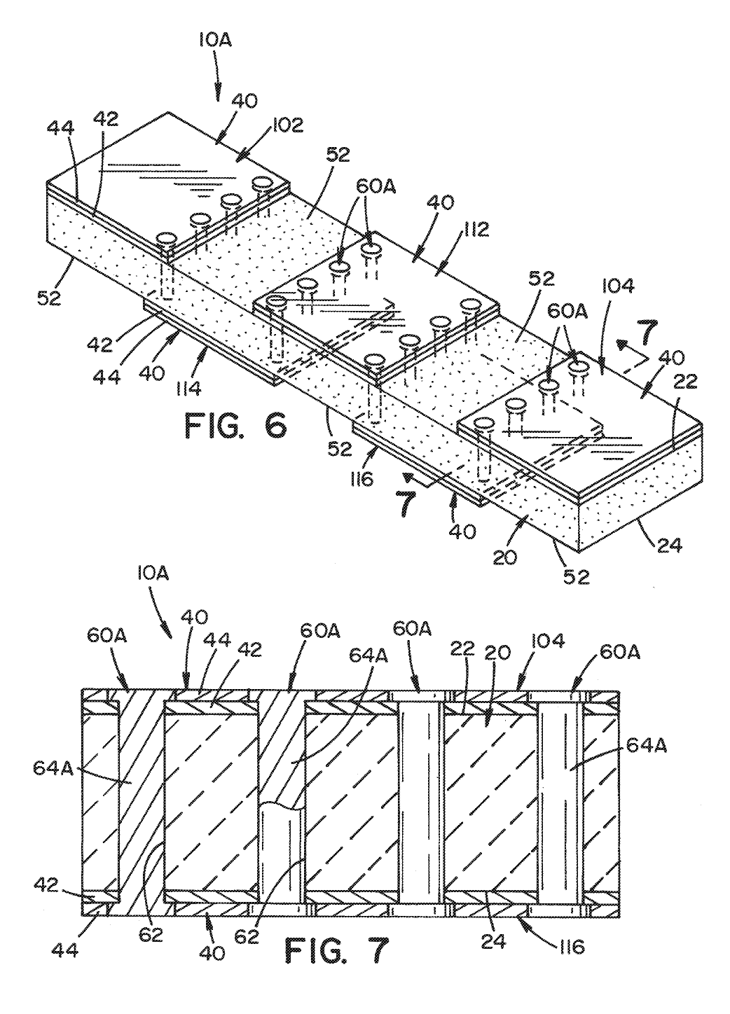

Referring now to FIGS. 6 and 7, these figures illustrate a PCB via fuse 10A according to a second embodiment of the present invention. In this embodiment, the number of through-hole vias is increased from four (4) to sixteen (16), and “plated” through-hole via 60 of the first embodiment is replaced with a “filled” through-hole via 60A of substantially the same dimensions as via 60. Accordingly, barrel portion 64 is replaced with a solid cylindrical-shaped barrel portion 64A. Barrel portion 64A is made of a conductive material, such as the plating material described above. Like vias 60, “filled” through-hole vias 60A provide an electrical connection between conductors 102, 104, 112, 114, 116, and serve as fuse elements of fuse 10A.

It should be appreciated that the desired electrical parameters of the PCB via fuse may be varied depending upon the number, dimensions, and materials of conducting members 40 and vias 60, 60A. For example, the current rating for the PCB via fuse may be increased by increasing the number of parallel vias 60, 60A, increasing the thickness of the wall of barrel portion 64 of vias 60, increasing the diameter of barrel portion 64A of vias 60A, and selecting a material for plating layer 44 having a lower resistance. The current rating for the PCB via fuse may be decreased by using a material for plating layer 44 having a lower melting point.

The desired electrical parameters of PCB via fuse 10, 10A can be obtained by selection of: the type of through-hole via (plated or filled); length (L) of the through-hole via; size of the inner and outer diameters of the through-hole via; the number of through-hole vias; the type of conductive material used for the plated or filled via; the type of conductive material used for the conducting members; the number and dimensions of the terminal and jumper conductors; the thickness, length, and width of substrate 20; the configuration of pads 66 (e.g., use of a thermal relief pad surrounding pads 66); and the like.

PCB via fuses 10, 10A are dimensioned to be received (e.g., snapped-in or soldered) inside a fuse housing (not shown). Fuse housing includes terminal elements that are electrically connected with terminal conductors 102, 104. The terminal elements are dimensioned to be received by terminal contacts of a fuse holder (not shown) Conventional arc quenching material (e.g., sand or the like) may be provided within the housing in the vicinity of vias 60, 60A.

As mentioned above, vias 60, 60A function as fuse elements of PCB via fuses 10, 10A. Accordingly, in response to a current overload condition, one or more vias 60, 60A will “open” due to melting, thereby disrupting the flow of current between terminal conductors 102 and 104.

The foregoing describes specific embodiments of the present invention. It should be appreciated that these embodiments are described for purposes of illustration only, and that numerous alterations and modifications may be practiced by those skilled in the art without departing from the spirit and scope of the invention. It is intended that all such modifications and alterations be included insofar as they come within the scope of the invention as claimed or the equivalents thereof.

Having described the invention, the following is claimed:

1. A PCB via fuse comprising:
a non-conductive substrate;
first and second terminal conductors formed on the substrate;
a plurality of j urn per conductors formed on the substrate; and
one or more through-hole vias electrically connecting the first and second terminal conductors and the plurality of jumper conductors, wherein said through-hole vias are fuse elements that melt in response to a current overload condition.

2. A PCB via fuse according to claim 1, wherein each of the first and second terminal conductors and each of the plurality of jumper conductors are conductive planes.

3. A PCB via fuse according to claim 2, wherein each conductive plane is comprised of a conductive base layer directly formed on a surface of the non-conductive substrate, and a conductive plating layer formed on base layer.

4. A PCB via fuse according to claim 3, wherein said base layer is comprised of copper.

5. A PCB via fuse according to claim 3, wherein said plating layer is comprised of at least one of: copper, silver, tin, gold, palladium, and nickel.

6. A PCB via fuse according to claim 1, wherein said through-hole vias are plated through-hole vias.

7. A PCB via fuse according to claim 1, wherein said through-hole vias are filled through-hole vias.

8. A PCB via fuse according to claim 1, wherein the through-hole vias include a barrel portion having a length (L) in a range of about 1 mm to about 5 mm.

9. A PCB via fuse according to claim 1, wherein said substrate has a thickness in a range of about 1 mm to about 2 mm.

10. A PCB via fuse according to claim 1, wherein said fuse has maximum current is in a range of about 100 mA. to about 30 A.
